(19) United States
(12) Patent Application Publication
(10) Pub. No.: US 2023/0013898 A1
(43) Pub. Date: Jan. 19, 2023

(54) SEMICONDUCTOR WAFER AND TEST METHOD

(71) Applicant: CHANGXIN MEMORY TECHNOLOGIES, INC., Hefei City (CN)

(72) Inventor: Zhongjie ZHANG, Hefei (CN)

(21) Appl. No.: 17/577,101

(22) Filed: Jan. 17, 2022

Related U.S. Application Data
(63) Continuation of application No. PCT/CN2021/120225, filed on Sep. 24, 2021.

(30) Foreign Application Priority Data
Jul. 19, 2021 (CN) 202110815109.0

(51) Int. Cl. H01L 21/66; G01R 31/28

(52) U.S. Cl. CPC H01L 22/34; G01R 31/2884

(57) ABSTRACT

Provided are a semiconductor wafer and a test method. The semiconductor wafer includes a substrate including multiple die regions and scribe line regions positioned between adjacent die regions; circuit test devices, positioned in the scribe line regions and provided with multiple test ports; anti-crack conductive structures, positioned in the scribe line regions and around the die regions, and positioned between the circuit test devices and the die regions; and at least one first wire for each circuit test device, one end of the first wire being connected to the corresponding test port, and the other end of the first wire being connected to the adjacent anti-crack conductive structure. The embodiments solve the problem of lack of wiring space for wires in the scribe line regions by utilizing the anti-crack conductive structures to provide test signals to the circuit test devices.

### CROSS-REFERENCE TO RELATED APPLICATIONS

This application is a continuation application of International Patent Application No. PCT/CN2021/120225, filed on Sep. 24, 2021, which claims priority to Chinese Patent Application No. 202110815109.0, filed on Jul. 19, 2021 and titled “Semiconductor wafer and test method”. The disclosures of International Patent Application No. PCT/CN2021/120225 and Chinese Patent Application No. 202110815109.0 are hereby incorporated by reference in their entireties.

### TECHNICAL FIELD

The disclosure relates to, but is not limited to a semiconductor wafer and a test method.

### BACKGROUND

In order to determine the yield of semiconductor wafers in a production process, generally wafer inspection may be performed on the semiconductor wafers. Wafer inspection may be performed to test functions and electrical parameters of components of wafers by utilizing a test probe and a tester.

A semiconductor wafer may be divided into die regions and scribe line regions. Generally, pad structures and circuit test devices may be arranged in the scribe line regions, and the pad structures may be connected to circuit test devices through wires, and electrical signals may be provided to the pad structures by a test probe and a tester, and then corresponding electrical signals may be provided to the circuit test devices for test.

However, no sufficient space can be provided for wiring wires in scribe line regions in prior art.

### SUMMARY

Embodiments of the disclosure provide a semiconductor wafer. The semiconductor wafer includes a substrate, including multiple die regions and scribe line regions positioned between adjacent die regions; circuit test devices, positioned in the scribe line regions and provided with multiple test ports; anti-crack conductive structures, positioned in the scribe line regions and around the die regions, and positioned between the circuit test devices and the die regions; and at least one first wire layer, one end of the first wire being connected to a corresponding test port, and another end of the first wire layer being connected to a corresponding adjacent anti-crack conductive structure.

In addition, embodiments of the disclosure further provide a test method. The test method includes the following steps: providing the semiconductor wafer described above; and providing first test signals to anti-crack conductive structures, and the first test signals being transmitted to the test ports of the circuit test devices through at least one first wire layer.

### BRIEF DESCRIPTION OF THE DRAWINGS

FIG. 1 illustrates a schematic structural diagram of a semiconductor wafer;

FIG. 2 illustrates a schematic structural diagram of a semiconductor wafer according to an embodiment of the disclosure;

FIG. 3 illustrates a schematic structural diagram of a cross-sectional view along the AA1 direction according to an embodiment of the disclosure;

FIG. 4 illustrates another schematic structural diagram of a cross-sectional view along the AA1 direction according to an embodiment of the disclosure;

FIG. 5 illustrates an enlarged partial schematic structural diagram of a cross-sectional view along the AA2 direction according to an embodiment of the disclosure;

FIG. 6 illustrates a schematic structural diagram of a semiconductor wafer according to another embodiment of the disclosure;

FIG. 7 illustrates a schematic structural diagram of a cross-sectional view along the AA3 direction according to another embodiment of the disclosure; and

FIG. 8 illustrates another schematic structural diagram of a cross-sectional view along the AA3 direction according to another embodiment of the disclosure.

### DETAILED DESCRIPTION

As seen from the background, no sufficient space can be provided for wiring wires in scribe line regions in prior art.

Unless otherwise defined, all technical and scientific terms used herein have the same meanings as those skilled in the art of the disclosure generally understand. The terms used herein in the specification of the disclosure are for the purpose of describing specific embodiments only and are not intended to limit the disclosure.

It should be understood that when an element or layer is referred to as being “on”, “adjacent to”, “connected to” or “coupled to” other elements or layers, it can be directly on other elements or layers, or can be adjacent to, connected to, or coupled to other elements or layers, or intervening elements or layers may be present. In contrast, when an element is referred to as being “directly on”, “directly adjacent to”, “directly connected to” or “directly coupled to” other elements or layers, there are no intervening elements or layers. It should be understood that although the terms “first”, “second”, “third”, and the like may be used to describe various elements, components, regions, layers, doping types, and/or portions, these elements, components, regions, layers, doping types, and/or portions should not be limited by these terms. These terms are used only to distinguish one element, component, region, layer, doping type or portion from another element, component, region, layer, doping type or portion. Thus, without departing from the teachings of the disclosure, the first element, component, region, layer, doping type or portion discussed below may be represented as a second element, component, region, layer or portion.

Spatial relationship terms such as “under . . . ”, “below . . . ”, “below”, “underneath . . . ”, “above”, “on”, etc., can be used to describe a relationship between one element or feature shown in the figure and other elements or features. It should be understood that in addition to the orientations shown in the figures, the spatial relationship terms also include different orientations of devices in use and operation. For example, if the device in the figures is turned over, elements or features described as “below other elements” or “under . . . ” or “under” will be oriented “on” the other elements or features. Therefore, the exemplary terms “below . . . ” and “under . . . ” can include both an orientation of above and below. In addition, the device may also include other orientations (for example, rotated by 90 degrees or other orientations), and the space descriptors used herein are interpreted accordingly.

When used herein, the singular forms “one”, “a(an)” and “the said/this” may also include plural forms, unless the context clearly dictates otherwise. It should also be understood that when the terms “composition” and/or “including” are used in this specification, the existence of the described features, integers, processes, operations, elements and/or components can be determined, but the presence or addition of one or more other features, integers, processes, operations, elements, components and/or groups are not excluded. Meanwhile, when used herein, the term “and/or” includes any and all combinations of related listed items.

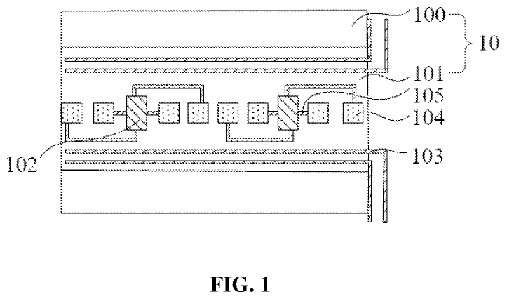

FIG. 1 illustrates a schematic structural diagram of a semiconductor wafer in related art. With reference to FIG. 1, the semiconductor wafer includes: a substrate 10, including die regions 100 and scribe line regions 101 positioned between adjacent die regions 100; circuit test devices 102, distributed in the scribe line regions 101 and provided with multiple test ports; anti-crack conductive structures 103, distributed in the scribe line regions 101 and around the die regions 100; pad structures 104, spaced apart from each other by the circuit test devices 102; and wires 105, and one end of the wire being connected to the pad structure 104 and the other end of the wire being connected to the test port of the circuit test device 102.

As shown in FIG. 1, when the circuit test device 102 is provided with more than two test ports, the wires 105 may include bent wires, which will occupy a considerable part of the space of the scribe line regions 101, and the layout space for the wires 105 will become increasingly small as the size of the scribe line regions 101 becomes increasingly small. In order to provide sufficient layout space to the wires 105, a commonly adopted method is to reduce the size of the pad structures 104 in exchange for layout space for the wires 105.

After analysis, when the size of the pad structures 104 is reduced, although the surrounding space may be further utilized, enough contact positions between a test probe and the pad structures 104 in the test of the semiconductor wafer cannot be ensured, and the test probe is prone to slipping out of the pad structures 104 or even directly stuck in the regions other than the pad structures 104, which may lead to unstable WAT (Wafer Acceptance Test) and unreliable test parameters, and the test probe is prone to being damaged. Therefore, reducing the size of the pad structures 104 is not appropriate for increasing insufficient space caused by the reduction of the scribe line regions 101.

Embodiments of the disclosure provide a semiconductor wafer and a test method. By utilizing anti-crack conductive structures to change the wire layout in scribe line regions, the area of the scribe line regions occupied by wires is reduced, and the space in the scribe line regions is better utilized.

To make the objectives, technical scheme and advantages of the embodiments of the disclosure to be understood more clearly, the embodiments of the disclosure will be described in detail below with reference to the drawings. However, those of ordinary skill in the art should understand that, numerous technical details will be described in the embodiments of the disclosure to enable the readers to better understand the disclosure, and even without the technical details and variations and modifications based on the following embodiments, the technical scheme claimed by the disclosure may further be implemented.

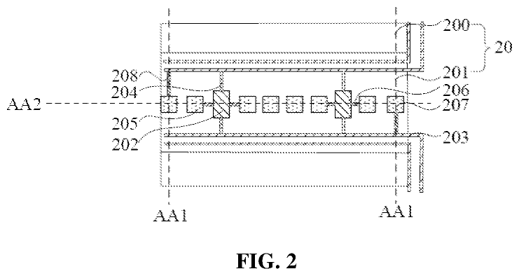

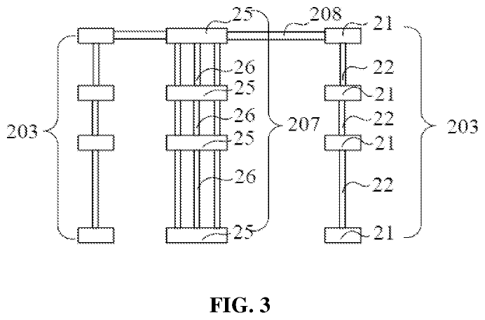

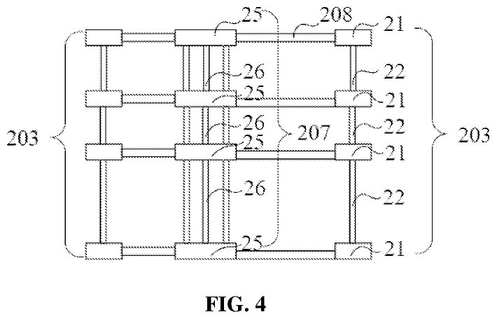

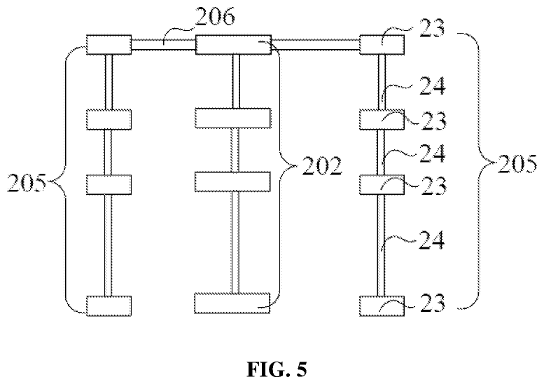

FIG. 2 to FIG. 5 illustrate schematic structural diagrams of a semiconductor wafer according to an embodiment of the disclosure. FIG. 2 illustrates a schematic structural diagram of a semiconductor wafer according to an embodiment of the disclosure. FIG. 3 illustrates a schematic structural diagram of a cross-sectional view of a stacked structure along the AA1 direction of FIG. 2. FIG. 4 illustrates another schematic structural diagram of a cross-sectional view of a stacked structure along the AA1 direction. FIG. 5 illustrates an enlarged partial schematic structural diagram of a cross-sectional view along the AA2 direction of FIG. 2.

With reference to FIG. 2 to FIG. 5 and according to some embodiments, a semiconductor wafer includes: a substrate 20 including multiple die regions 200 and scribe line regions 201 positioned between adjacent die regions 200; circuit test devices 202, positioned in the scribe line regions 201 and provided with multiple test ports; anti-crack conductive structures 203, positioned in the scribe line regions 201 and around the die regions 200 and positioned between the circuit test devices 202 and the die regions 200; and at least one first wire layer 204, an end of the first wire layer 204 being connected to a corresponding test port and another end of the first wire layer 204 being connected to a corresponding anti-crack conductive structure 203.

The test ports may be connected to the anti-crack conductive structures 203 by providing at least one first wire layer 204, the space occupied by the wires in the scribe line regions 201 can be reduced. For a same circuit test device 202, the number of the first pad structures 205 required for test of the circuit test device 202 is reduced, and therefore, the surface area of the first pad structures 205 may be increased, so that the first pad structures 205 may have enough positions to contact with a test probe, and the phenomenon that the test probe slips out of the first pad structures 205 or is stuck to an regions other than the first pad structures 205 can be avoided, thereby improving the reliability of test results and preventing the test probe from being damaged.

The semiconductor wafer provided by the embodiments will be described in more detail below with reference to the drawings.

The substrate 20 may be a wafer made of a semiconductor single crystal material. For example, the substrate 20 may be a silicon substrate, a germanium substrate, a silicon germanium substrate, a gallium arsenide substrate and the like. Silicon is most commonly utilized, and the silicon substrate is taken as an example according to the embodiments.

The substrate 20 may be provided with a stacked structure and the stacked structure may include a dielectric layer and a conductive layer. According to some embodiments, 4 conductive layers may be arranged. According to other embodiments, 8 conductive layers may be arranged. It should be understood that the number of conductive layers may be adjusted according to actual requirements.

The die regions 200 may include functional device regions and seal rings (SR), and the seal rings may be arranged around the functional device regions. The functional device regions are central circuit regions of an integrated circuit of a chip. The seal rings are multi-layer metal layers arranged to protect the functional device regions. The seal rings can protect the functional device regions from being invaded by cracks during scribing.

The scribe line regions 201 are scribing regions which define multiple dies scribed by the semiconductor wafer. The seal rings are positioned between the scribe line regions 201 and the functional device regions.

The circuit test devices 202 are configured to simulate components in the tested die regions 200, such as components like Metal-Oxide-Semiconductor (MOS) transistors and memory capacitors in the functional device regions. In a process of manufacturing a chip, same components as those of the functional device regions may be manufactured in the scribe line regions 201 through a same process, and the quality of the same components in the die regions 200 are indirectly fed back by the test of the circuit test devices 202 in the scribe line regions 201.

The circuit test devices 202 may be provided with different numbers of test ports according to the types of components simulated by the circuit test devices 202. For example, when the circuit test devices 202 simulate MOS transistors, each circuit test device 202 may be provided with four test ports; and when the circuit test devices 202 simulate memory capacitors, each circuit test device 202 may be provided with two test ports, etc. The situation that the circuit test devices 202 simulate MOS transistors is taken as an example according to the embodiments.

The circuit test devices 202 may be arranged in the scribe line regions 201 in a spaced mode. It should be understood that the number of circuit test devices 202 may be reasonably set according to the size of the scribe line regions 201 and the test requirements.

The anti-crack conductive structures 203 may be positioned in the scribe line regions 201 and around the die regions 200. According to some embodiments, two anti-crack conductive structures 203 parallel to each other may be arranged for each die region 200, and there is a distance between the two anti-crack conductive structures 203. The anti-crack conductive structures 203 are configured to further protect the die regions 200 from being invaded by cracks generated when the semiconductor wafer is scribed. According to some embodiments, anti-crack conductive structures 203 may further be configured to provide electrical signals to circuit test devices 202.

The anti-crack conductive structures 203 may include multiple stacked third conductive layers 21 and third conductive columns 22 electrically connected to adjacent third conductive layers 21.

The anti-crack conductive structures 203 may be arranged on opposite sides of the circuit test devices 202, and the circuit test devices 202 may be connected to the anti-crack conductive structures 203 on least one side through first wire layers 204. The anti-crack conductive structures 203 are adopted to reduce the wiring area required by the scribe line regions 201, and the number of first pad structures 205 required by the test of the circuit test devices 202 may further be reduced, so that the number of circuit test devices 202 may be increased as needed, and the space utilization rate of the scribe line regions 201 is improved.

According to some embodiments, circuit test devices 202 may be connected to anti-crack conductive structures 203 on two sides through first wire layers 204.

Specifically, according to some embodiments, two first wire layers 204 may be arranged, one is connected to the anti-crack conductive structure 203 on one side of a corresponding circuit test device 202 and the other is connected to the anti-crack conductive structure 203 on the other side of the corresponding circuit test device 202. Test signals may be provided to the circuit test device 202 by providing two test signals to the anti-crack conductive structures 203 on two sides of the circuit test device 202. The number of first pad structures 205 required by a circuit test device 202 is reduced, so that the number of the circuit test devices 202 or the surface area of the first pad structures 205 may be increased as required. Therefore, enough contact positions between a test probe and the first pad structures 205 are ensured, and the problem that the test probe slips out of the first pad structures 205 or is stuck to regions other than the first pad structures 205 is avoided, thereby improving the reliability of test results and preventing the test probe from being damaged. According to other embodiments, more first wire layers may further be arranged for a circuit test device, and two anti-crack conductive structures may be distributed on two sides of the circuit test device, so that the circuit test device may be connected to conductive layers of different anti-crack conductive structures through the first wire layers, and then electrical signals may be provided to test ports of the circuit test device through the anti-crack conductive structures of different layers.

It should be noted that, according to some embodiments, a circuit test device may be provided with two test ports, and then the test of the circuit test device may be completed by utilizing two first wire layers and corresponding anti-crack conductive structures. Specifically, corresponding test signals may be provided to the anti-crack conductive structures, the test signals may be transmitted to the test ports of the circuit test device via the first wire layers, and the test signals transmitted from the test ports to the anti-crack conductive structures via the first wire layers may further be collected.

The semiconductor wafer may further include: multiple first pad structures 205, positioned in the scribe line regions 201 and spaced apart from each other by the circuit test devices 202; and at least one second wire layer 206, an end of the second wire layer 206 being connected to a corresponding first pad structure 205 and the other end of the second wire layer 206 being connected to a corresponding circuit test device 202. The functional test of the circuit test device 202 may be completed by providing electrical signals to the rest test ports of the circuit test device 202 by utilizing the first pad structures 205. It should be understood that the number of the first pad structures 205 required by a circuit test device 202 is related to the number of the test ports of the circuit test device 202. For example, when a circuit test device 202 is provided with 4 test ports, the number of the first pad structures 205 required by the circuit test device 202 is 2.

According to some embodiments, two first pad structures 205 may be arranged on opposite sides of a circuit test device 202, and two second wire layers 206 may be arranged for the circuit test device 202. One second wire layer 206 may be connected to the corresponding first pad structure 205 on a side of the circuit test device 202, and the other second wire layer 206 is connected to the corresponding first pad structure 205 on the other side of the circuit test device 202. Required electrical signals may be provided to four test ports of the circuit test device 202 by utilizing the two first pad structures 205 and the anti-crack conductive structures 203 on opposite sides of the circuit test device 202 to complete the test of each circuit test device 202. A relatively small area of scribe line regions 201 may be occupied by first wire layers 204 and the second wire layers 206, thereby achieving the purpose of reducing the wiring area of the scribe line regions 201.

Therefore, two of four test ports of a circuit test device 202 may be connected to the corresponding anti-crack conductive structures 203 on opposite sides of the circuit test device 202, and the other two test ports may be connected to two corresponding adjacent first pad structures 205. Then, the test of each circuit test device 202 may be completed through the anti-crack conductive structures 203 and the first pad structures 205.

Further, the first pad structure 205 may include: multiple stacked first conductive layers 23 and first conductive columns 24 electrically connected to the first conductive layers 23, and the second wire layer 206 may be positioned in a same layer as and connected to at least one of the first conductive layers 23 of the corresponding first pad structure 205. By utilizing the stacked structure, electrical signals may be provided to the first pad structure 205 through any of the first conductive layers 23.

According to some embodiments, the semiconductor wafer may further include: multiple second pad structures 207, positioned in scribe line regions 201 and spaced apart from each other by first pad structures 205; and at least one third wire layer 208, an end of the third wire layer 208 being connected to a corresponding second pad structure 207 and the other end of the third wire layer 208 being connected to a corresponding anti-crack conductive structure 203.

According to some embodiments, a second pad structure 207 may be positioned on the side, away from a corresponding circuit test device 202, of a corresponding first pad structure 205. Such arrangement can facilitate the circuit test devices 202 to be connected to the first pad structures 205 in scribe line regions 201.

The second pad structures 207 may be electrically connected to anti-crack conductive structures 203. Therefore, a test probe may be adopted to contact the second pad structures 207 to enable test signals to reach the anti-crack conductive structures 203 via the second pad structures 207, or enable test signals to reach the second pad structures 207 via the anti-crack conductive structures 203 to be detected by the test probe. Further, according to some embodiments, two second pad structures 207 may be electrically connected to anti-crack conductive structures 203, one second pad structure 207 is electrically connected to the corresponding anti-crack conductive structure 203 on one side of a corresponding circuit test device 202 and the other second pad structure 207 is electrically connected to the corresponding anti-crack conductive structure 203 on the opposite side of the corresponding circuit test device 202. Through the two second pad structures 207, electrical signals may be provided to the anti-crack conductive structures 203 on opposite sides of the corresponding circuit test device 202, thereby providing electrical signals to two test ports of the corresponding circuit test device 202.

It should be understood that, according to some embodiments, second pad structures 207 may be configured to provide electrical signals to anti-crack conductive structures 203, thereby providing electrical signals to circuit test devices 202, which facilitates providing signals to the second pad structures 207 when the second pad structures 207 are configured to provide electrical signals to the anti-crack conductive structures 203. According to other embodiments, electrical signals may further be provided directly to anti-crack conductive structures from the outside, so that second pad structures may not be required, thereby saving space in scribe line regions, so that the number of circuit test devices or the area of first pad structures may be increased as required.

Further, the second pad structure 207 may include multiple stacked second conductive layers 25 and second conductive columns 26 electrically connected to adjacent second conductive layers 25. The anti-crack conductive structure 203 may include multiple stacked third conductive layers 21 and third conductive columns 22 electrically connected to adjacent third conductive layers 21. The third wire layer 208 may be positioned and connected to in the same layer as at least one second conductive layer 25 and the third conductive layer 21.

According to some embodiments, as shown in FIG. 3, FIG. 3 illustrates a schematic diagram of a cross-sectional view of the stacked structure of second pad structures 207 on two sides along the AA1 direction of FIG. 2. Anti-crack conductive structures 203 may be electrically connected to the second pad structures 207 by connecting top third conductive layers 21 to the second conductive layers 25. It should be understood that the anti-crack conductive structures 203 may further be electrically connected to the second pad structures 207 by connecting any third conductive layers 21 to the corresponding second conductive layers 25. According to other embodiments, as shown in FIG. 4, FIG. 4 illustrates a schematic diagram of a cross-sectional view of the stacked structure of second pad structures 207 on two sides along the AA1 direction of FIG. 2. The stability of electrical signals may be improved by connecting multiple third conductive layers 21 to the second conductive layers 25. For example, a third conductive layer 21 may be connected to a corresponding second conductive layer 25 in a same layer, or at least two third conductive layers 21 may be connected to corresponding second conductive layers 25 in the same layers. The flexibility of test may further be improved, for example, by applying electrical signals to each second conductive layer 25, and then applying the electrical signals to test ports of circuit test devices 202 through anti-crack conductive structures 203 to measure the electrical performance of components in each layer respectively, and to avoid finding performance problems of the components only in the final test.

It should be understood that, according to some embodiments, multiple circuit test devices in scribe line regions may be provided with different test ports. For example, in a scribe line region, there are both the circuit test device configured to simulate the test of MOS transistors and the circuit test device configured to simulate the test of memory capacitors, etc. Correspondingly, corresponding electrical signals may be provided to the corresponding test ports according to different circuit test devices.

By utilizing the anti-crack conductive structures 203 on opposite sides of the circuit test devices 202, the first pad structures 205 required by the circuit test devices 202 are reduced, thereby reducing the number of first pad structures 205 and further improving the space utilization rate of the scribe line regions 201. Meanwhile, the surface area of the first pad structures 205 may further be relatively increased as required, so that enough contact positions between a test probe and the first pad structures 205 may be ensured, and the problem that the test probe slips out of the first pad structures 205 or is stuck to regions other than the first pad structures 205 is avoided, thereby improving the reliability of the test results and preventing the test probe from being damaged. Alternatively, the number of circuit test devices 202 may be increased as required to simulate and test more components in the die regions 200, and further determine the yield of components in the die regions 200 more accurately.

Another embodiment of the disclosure further provides a semiconductor wafer. The semiconductor wafer according to the embodiment is substantially the same as that of the preceding embodiments. The main differences include that: an anti-crack conductive structure on only one side of each circuit test device is utilized according to some embodiments. The semiconductor wafer according to another embodiment of the disclosure will be described below with reference to the drawings, and it should be noted that illustration of same or corresponding parts as those of the foregoing embodiments will not be repeated and the illustration of the foregoing embodiments should be referred to for understanding.

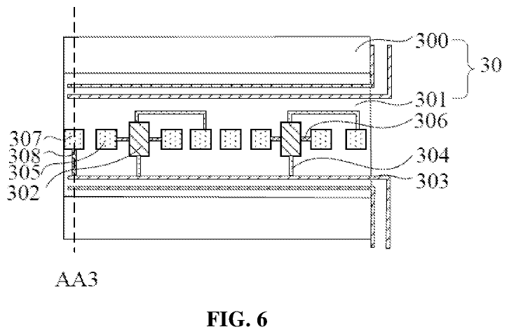

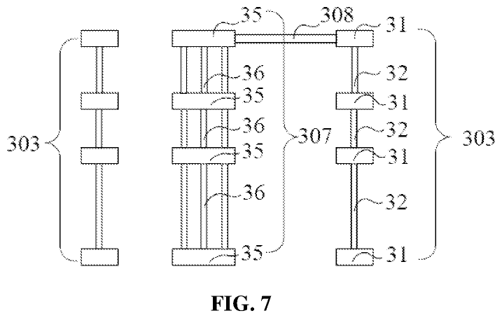

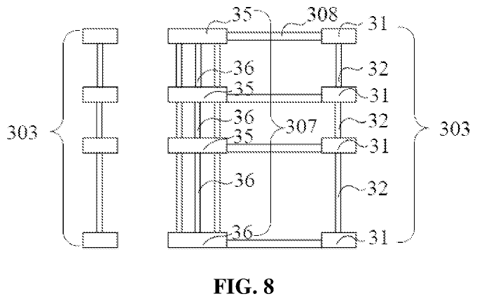

FIG. 6 illustrates a schematic structural diagram of the semiconductor wafer according to another embodiment of the disclosure. FIG. 7 illustrates a schematic structural diagram of a cross-sectional view along the AA3 direction of FIG. 6. FIG. 8 illustrates another schematic structural diagram of a cross-sectional view along the AA3 direction of FIG. 6.

With reference to FIG. 6, the semiconductor wafer includes a substrate 30, die regions 300, scribe line regions 301, circuit test devices 302, anti-crack conductive structures 303, first wire layers 304, first pad structures 305, second wire layers 306, second pad structures 307, and third wire layers 308.

According to some embodiments, one first wire layer 304, three first pad structures 305, and three second wire layers 306 may be arranged for a circuit test device 302. Each second wire layer 306 may be electrically connected to the circuit test device 302 and a corresponding first pad structure 305. Required electrical signals may be provided to four test ports of the circuit test device 302 by utilizing the three first pad structures 305 and a corresponding anti-crack conductive structure 303 on one side of the circuit test device 302 to realize the functional test of the circuit test device 302. The area of a scribe line region 301 occupied by the anti-crack conductive structure 303 on one side and three first pad structures 305 is smaller than that of a scribe line region 301 occupied by four first pad structures 305, thereby achieving the purpose of reducing the wiring area of the scribe line regions 301.

The three second wire layers 306 may include: two straight wires electrically connected to a corresponding circuit test device 302 and a corresponding adjacent first pad structure 305; and a bent wire electrically connected to the corresponding circuit test device 302 and a corresponding first pad structure 305 farthest from the corresponding circuit test device 302. The required electrical signals may be provided to the four test ports of the circuit test device 302 through the three second wire layers 306 and one first wire layer 304 to realize the functional test of the circuit test device 302.

According to some embodiments, with reference to FIG. 7, anti-crack conductive structures 303 may be electrically connected to second pad structures 307 by connecting top third conductive layers 31 to the second conductive layers 35. It should be understood that the anti-crack conductive structures 303 may further be electrically connected to the second pad structures 307 by connecting any third conductive layers 31 to the second conductive layers 35. According to other embodiments, as shown in FIG. 4, the stability of electrical signals may be improved by connecting multiple third conductive layers 31 to the second conductive layers 35. For example, a third conductive layer 31 may be connected to a corresponding second conductive layer 35 in every same layer, or at least two third conductive layers 31 are connected to corresponding second conductive layers 35 at the same two layers. The flexibility of test may be further improved, for example, by applying electrical signals to each second conductive layer 35, and then applying electrical signals to test ports of circuit test devices 302 through anti-crack conductive structures 303 to measure the electrical performance of components in each layer respectively, and avoid finding performance problems of the components only in the final test.

According to some embodiments, a circuit test device 302 may be tested by providing electrical signals to an anti-crack conductive structure 303 on one side of the circuit test device 302 and to three first pad structures 305. By utilizing the anti-crack conductive structure 303 on one side of the circuit test device 302, the wiring mode in the space of the scribe line regions 301 may be changed, thereby improving the space utilization rate of the scribe line regions 301. Moreover, the area of the first pad structures 305 may be relatively increased as required to improve the contact stability between a test probe and the first pad structures 305, or the number of circuit test devices 302 may be increased as required to simulate and test more components in die regions 300, and further determine the yield of components in the die regions 300 more accurately.

Further, embodiments of the disclosure further provide a test method, including: providing the semiconductor wafer according to the foregoing embodiments; and providing second test signals to the first pad structures by providing first test signals to the anti-crack conductive structures and further to the test ports of the circuit test devices through first wire layers, the second test signals being transmitted to the test ports of the circuit test devices through the second wire layers.

According to some embodiments, first test signals may be operational power signals or ground signals. Generally, circuit test devices 302 require operational power signals and ground signals. By providing operational power signals or ground signals to the anti-crack conductive structures 303, all the circuit test devices 302 in scribe line regions 301 may be utilized to facilitate the test of all the scribe line regions 301. According to other embodiments, first test signals may further be square wave signals or AC signals.

The number of bent wires may be reduced by providing corresponding electrical signals to circuit test devices 302 by utilizing anti-crack conductive structures 303, thereby reducing the space for wire layout, so that the number of circuit test devices 302 may be increased as required or the area of the first pad structures 305 may be relatively increased as required. Therefore, enough contact space between a test probe and the first pad structures 305 can be ensured, and the problem that the test probe slides out of the first pad structures 305 or is stuck to the regions other than the first pad structures 305 can be avoided, thereby improving the reliability of the test results and preventing the test probe from being damaged.

Those of ordinary skill in the art should understand that the foregoing embodiments are specific embodiments for implementing the disclosure and in practical application, variations may be made in terms of form and detail thereof without departing from the spirit and scope of the disclosure. Any person skilled in the art may make variations and modifications without departing from the spirit and scope of the disclosure, therefore the scope of the disclosure should be defined by the scope of the claims.

### INDUSTRIAL APPLICABILITY

According to the embodiments of the disclosure, a semiconductor wafer includes a substrate, the substrate including multiple die regions and scribe line regions positioned between adjacent die regions; circuit test devices, positioned in the scribe line regions and provided with multiple test ports; anti-crack conductive structures positioned in the scribe line regions and around the die regions, and positioned between the circuit test devices and the die regions; and at least one first wire, one end of the first wire being connected to a corresponding test port, and the other end of the first wire being connected to a corresponding adjacent anti-crack conductive structure. The embodiments of the disclosure solve the problem of lack of space for wiring wires in scribe line regions by utilizing anti-crack conductive structures to provide test signals to circuit test devices.

1. A semiconductor wafer, comprising:
a substrate, wherein, the substrate comprises multiple die regions and scribe line regions between adjacent die regions;
circuit test devices, positioned in the scribe line regions and provided with multiple test ports;
anti-crack conductive structures, positioned in the scribe line regions and around the die regions, and positioned between the circuit test devices and the die regions; and
at least one first wire layer, wherein an end of the first wire layer is connected to a corresponding test port, and another end of the first wire layer is connected to a corresponding adjacent anti-crack conductive structure.

2. The semiconductor wafer of claim 1, wherein the anti-crack conductive structures are arranged on two opposite sides of the circuit test devices; and the circuit test device is connected to the anti-crack conductive structure on at least one side through the first wire layer.

3. The semiconductor wafer of claim 2, wherein there are two first wire layers, one is connected to the anti-crack conductive structure on a side of the circuit test device, and the other is connected to the anti-crack conductive structure on the other side of the circuit test device.

4. The semiconductor wafer of claim 1, further comprising:
multiple first pad structures, positioned in the scribe line regions and spaced apart from each other by the circuit test devices; and
at least one second wire layer, wherein an end of the second wire layer is connected to the first pad structure, and the other end of the second wire layer is connected to the test port.

5. The semiconductor wafer of claim 4, wherein the first pad structure is arranged on two opposite sides of the circuit test device; there are two second wire layers, one is connected to the first pad structure on a side of the circuit test device, and the other is connected to the first pad structure on another side of the circuit test device.

6. The semiconductor wafer of claim 4, wherein there are three first pad structures electrically connected to the circuit test device; and there are three second wire layers, each of the three second wire layers is electrically connected to the circuit test device and the corresponding first pad structure.

7. The semiconductor wafer of claim 6, wherein the three second wire layers comprise:
two straight wires, electrically connected to the circuit test device and an adjacent first pad structure; and
a bent wire, electrically connected to the circuit test device and the first pad structure farthest from the circuit test device.

8. The semiconductor wafer of claim 4, wherein the first pad structure comprises: multiple stacked first conductive layers and first conductive columns electrically connected to adjacent first conductive layers,
wherein the second wire layer is positioned in a same layer as at least one of the first conductive layers and is connected to the at least one of the first conductive layers.

9. The semiconductor wafer of claim 4, further comprising:
multiple second pad structures, positioned in the scribe line regions and spaced apart from each other by the first pad structures; and
at least one third wire layer, wherein an end of the third wire layer is connected to the second pad structure, and another end of the third wire layer is connected to the anti-crack conductive structure.

10. The semiconductor wafer of claim 9, wherein the second pad structure comprises: multiple stacked second conductive layers and second conductive columns electrically connected to adjacent second conductive layers;
the anti-crack conductive structure comprises multiple stacked third conductive layers and third conductive columns electrically connected to adjacent third conductive layers; and
the third wire layer is positioned in a same layer as at least one of the second conductive layers as well as the third conductive layers and is connected to the at least one of the second conductive layers as well as the third conductive layers.

11. The semiconductor wafer of claim 9, wherein the second pad structure is positioned on a side, away from the circuit test device, of the first pad structure.

12. The semiconductor wafer of claim 9, wherein there are two second pad structures electrically connected to the anti-crack conductive structures, one second pad structure is electrically connected to the anti-crack conductive structure on a side of the circuit test device, and the other second pad structure is electrically connected to the anti-crack conductive structure on an opposite side of the circuit test device.

13. A test method, comprising:
providing a semiconductor wafer; and
providing first test signals to anti-crack conductive structures, wherein the first test signals are transmitted to test ports of circuit test devices through first wire layer,
wherein the semiconductor wafer comprises:
a substrate comprising multiple die regions and scribe line regions between adjacent die regions;
circuit test devices, positioned in the scribe line regions and provided with multiple test ports;
anti-crack conductive structures, positioned in the scribe line regions and around the die regions, and positioned between the circuit test devices and the die regions; and
at least one first wire layer, wherein an end of the first wire layer is connected to a corresponding test port, and another end of the first wire layer is connected to a corresponding adjacent anti-crack conductive structure.

14. The test method of claim 13, wherein
the semiconductor wafer further comprises:
multiple first pad structures, positioned in the scribe line regions and spaced apart from each other by the circuit test devices; and
at least one second wire layer, wherein an end of the second wire layer is connected to the first pad structure, and another end of the second wire layer is connected to the test port; and
the test method further comprises:
providing second test signals to the first pad structures, wherein the second test signals are transmitted to the test ports of the circuit test devices through the second wire layers.

15. The test method of claim 13, wherein the first test signals comprise operational power signals or ground signals.

16. The test method of claim 13, wherein the anti-crack conductive structures are arranged on two opposite sides of the circuit test devices; and the circuit test device is connected to the anti-crack conductive structure on at least one side through the first wire layer.

17. The test method of claim 14, wherein there are two first wire layers, one is connected to the anti-crack conductive structure on a side of the circuit test device, and the other is connected to the anti-crack conductive structure on the other side of the circuit test device.

18. The test method of claim 14, wherein the first pad structure is arranged on two opposite sides of the circuit test device; there are two second wire layers, one is connected to the first pad structure on a side of the circuit test device, and the other is connected to the first pad structure on another side of the circuit test device.

19. The test method of claim 14, wherein there are three first pad structures electrically connected to the circuit test device; and there are three second wire layers, each of the three second wire layers is electrically connected to the circuit test device and the first pad structure.

20. The test method of claim 19, wherein the three second wire layers comprise:
two straight wires, electrically connected to the circuit test device and an adjacent first pad structure; and
a bent wire, electrically connected to the circuit test device and the first pad structure farthest from the circuit test device.
